(19) United States
(12) Patent Application Publication
(10) Pub. No.: US 2025/0048775 A1
(43) Pub. Date: Feb. 6, 2025

(54) CAPPED SEMICONDUCTOR BASED SENSOR AND METHOD FOR ITS FABRICATION

(71) Applicant: Senseair AB, Delsbo (SE)

(72) Inventor: Stephan Schröder, Bålsta (SE)

(21) Appl. No.: 18/719,560

(22) PCT Filed: Dec. 19, 2022
(86) PCT No.: PCT/SE2022/051205

§ 371 Date: Jun. 13, 2024

(30) Foreign Application Priority Data
Dec. 22, 2021 (SE) 2151594-5

(51) Int. Cl. H01L 31/18; G01N 21/3504; H01L 31/12

(52) U.S. Cl. CPC H01L 31/1876; G01N 21/3504; H01L 31/12

(57) ABSTRACT

A method for fabricating semiconductor based sensor devices with sensors which are in communication with the environment surrounding the sensor devices, and such a sensor device is described. The method comprises the steps of providing a semiconductor-based device wafer, fabricating a plurality of sensors on the semiconductor-based device wafer, providing a capping wafer, and attaching the capping wafer on the device wafer with each sensor arranged below a recess of the capping wafer. The capping wafer comprises at least one gas permeable section between each recess and the second side, to provide a gas passage between the recess and the environment surrounding the sensor device. The method further comprises the steps of applying a protective layer on all gas permeable sections of the capping wafer, dividing the device wafer and the attached capping wafer into individual sensor devices, and removing the protective layer from all gas permeable sections.

### TECHNICAL FIELD

The present invention relates to a semiconductor-based sensor device and a method for its fabrication.

### BACKGROUND ART

Semiconductor-based sensor devices are increasingly used to sense various entities. By using semiconductor-based sensor devices the dimensions of the sensor devices may be kept small at the same time as the cost can be kept low. One type of semiconductor-based sensor devices are photonic gas sensors. Photonic gas sensors rely on the interaction of light with a gas and the measurement of the attenuation of the light by the interaction of light with the gas. One type of photonic sensor comprises a waveguide, a light source and a detector. This type of sensor utilises the principle of exciting, with the light source, an electromagnetic field in the waveguide, which electromagnetic field comprises an evanescent wave. Typically, the evanescent wave refers to the portion of the electromagnetic field that propagates outside of the waveguide but is related to the propagating electromagnetic wave in the waveguide. The evanescent wave interacts with the gas surrounding the waveguide. The wavelength of the light is chosen to correspond to an absorption peak of the gas to be sensed. For most gases of interest, the absorption peak is in the infrared wavelength region. In order to minimize the effect, on the evanescent wave, of compromising factors other than the gas, the waveguide may be configured to be partially free hanging. This may be achieved by having the waveguide supported on posts/pillars extending from the surface of the substrate. Such a sensor consists of fragile micro- and nanostructures, in the form of, e.g., gratings for coupling of light into the waveguide, one or more waveguides, posts/pillars, and multimode interference splitters and combiners, photonic resonators or other photonic components. Such sensors can be fabricated in a semiconductor material using conventional semiconductor fabrication approaches, wherein a plurality of sensor devices are fabricated on a common wafer. This is a cost effective fabrication method that has been broadly used for the fabrication of micro- and nanoelectronics. The handling of these devices during and after the fabrication is problematic and a common approach to protect the devices is wafer level packaging (WLP) that is primarily based on attaching a capping wafer on the device wafer, which contains the photonic sensor devices. By providing a capping wafer, the photonic structures of the sensors become protected from damages from the outside. In order to allow gas to come in contact with the waveguide it is necessary to provide gas entrances through the capping wafer or the device wafer.

After having attached the capping wafer, the device wafer and the attached capping wafer has to be divided into individual sensor devices. Such individualization is traditionally called singulation. Traditionally, the dividing process has been performed utilizing a rotating blade. During the dividing process with a rotating dicing blade, particles and heat are generated. The process of sawing a wafer into a single chips is usually called die sawing or dicing. For cooling purposes, water is sprayed onto the blade and wafer during die sawing or dicing, i.e., the dividing process. To prevent water and/or particles from coming into contact with the structures of the sensor, the sensors need to be fully encapsulated during the dicing process, such that water and particles cannot access the devices.

The problem of avoiding particles and water from entering a device exists also for micro-electromechanical systems, MEMS, which needs to be in contact with the atmosphere. Semiconductor-based MEMS devices and photonic sensor devices both constitute devices with micro- and/or nanostructures. MEMS devices are described in US 2006/0001114 A1, in which a lid is attached to a substrate with MEMS. Openings are provided in the lid, which openings are filled with a protective gel. After having attached the lid on the substrate with the MEMS a dicing step is performed for producing single chips. After dicing the protective gel is removed such that the MEMS get in contact with the atmosphere.

When semiconductor based sensor devices comprising micro- and/or nanostructures are used in a dusty environment the dust affects the operation of the sensor devices negatively.

JP2020-095035 describes a gas sensor comprising a first and a second substrate attached to each other, with an optical waveguide arranged on the first substrate and a light emitting element arranged on the second substrate.

WO2016060619 A1 describes an optical waveguide structure and an optical gas sensor and methods of fabrication thereof.

### SUMMARY OF THE INVENTION

An object of the present invention is to provide a sensor device comprising micro- and/or nanostructures which are configured to interact with the environment and a method for fabricating such a sensor device, wherein the sensor device is less sensitive to dust and water during operation and fabrication than conventional sensor devices.

Another object of the present invention is to provide a sensor device comprising micro- and/or nanostructures which are configured to interact with the environment and a method for fabricating such a sensor device, which is an alternative to the sensor devices according to the prior art.

At least one of these objects is fulfilled with a sensor device and a method according to the independent claims.

Further advantages are achieved with the features of the dependent claims.

According to a first aspect, a method is provided for fabricating semiconductor-based sensor devices comprising sensor parts, which are configured to interact with the environment surrounding the sensor devices. The method comprises the steps of providing a semiconductor-based device wafer, fabricating a plurality of sensor parts comprising micro- and/or nanostructures on different device areas on a device side of the device wafer, providing a capping wafer comprising a first side and a second side and a plurality of recesses on the first side, and attaching the first side of the capping wafer on the device side of the device wafer with each sensor part arranged below a recess such that a cavity is formed between each recess and the device wafer. The method is characterized in that the capping wafer is in contact with the device wafer in contact areas arranged at the periphery of the recesses. The method is also characterized in that the capping wafer comprises at least one gas permeable section between each recess and the second side, to provide a gas passage between the recess and the environment surrounding the sensor device. The method is characterized in that it also comprises the steps of applying a protective layer on all gas permeable sections of the capping wafer, dividing the device wafer and the attached capping wafer into individual sensor devices, and removing the protective layer from all gas permeable sections.

With the method according to the first aspect, a favourable method for fabricating a sensor device with gas permeable sections is provided. The gas permeable sections provide some protection against dust and water coming into contact with the sensor during operation of the sensor device after fabrication. The protective layer that is applied on all gas permeable sections before dividing prevents particles and cooling water from coming into contact with the gas permeable sections during dividing. During operation the gas permeable section enables gas exchange between the sensor parts and the environment surrounding the sensor device.

The protective layer may be of many different materials, such as, e.g., a polymer or a metal, depending on the choice of gas permeable material.

The removal of the protective layer may be performed using any known technique, such as, e.g., etching and dissolving.

The sensor parts do not have to comprise all parts necessary for a functioning sensor but may comprise only the parts which are configured to interact with the environment.

The capping wafer may be made entirely of a gas permeable material. This facilitates the fabrication of the capping wafer. The term capping wafer is used in this application in the in the meaning of a thin disk resembling a wafer.

Alternatively, the capping wafer may be semiconductor-based and comprise gas permeable sections. According to this alternative, the capping wafer may comprise a semiconductor-based layer having apertures. The apertures may, according to a first alternative, be filled with gas permeable material. According to a second alternative, the semiconductor-based capping wafer may comprise a gas permeable layer on top of the semiconductor-based layer having apertures such that the apertures define the gas permeable sections.

The contact areas may completely enclose each recess after the step of dividing such that gas exchange is possible only through the gas permeable section. In this way, the device is simplified in that all gas exchange is through the gas permeable material of the capping wafer and not through any gap between the device wafer and the capping wafer. Alternatively, it is possible to have gas permeable channels apart from the gas permeable section.

In case the protective layer is a polymer layer, the application of the polymer layer may be performed by laminating a polymer layer on the capping wafer. Alternatively, the application of a polymer layer may be performed in two steps, wherein a liquid polymer is applied in a first step and wherein the polymer is heat treated in a second step to solidify the polymer.

The step of applying a polymer layer on all gas permeable sections may comprise applying a protective layer covering the second side of the capping wafer. This is an easy method for application of the polymer layer. The application of the protective layer may be performed by a standard spinning procedure. Alternatively, the step of applying a polymer layer on all gas permeable sections may comprise applying a plurality of polymer layers, wherein each polymer layer covers at least one gas permeable section.

The gas permeable material may consist of a porous material. The porous material may be applied as a continuous layer above a semiconductor base layer of the capping wafer, wherein the semiconductor base layer is provided with openings defining the gas permeable sections. The porous material may be attached to the semiconductor base layer by bonding or gluing. The part of the porous layer that covers an opening is a gas permeable section. Alternatively, the openings in the semiconductor base layer may be filled with a porous material such that the gas permeable sections are separate gas permeable sections. According to another alternative, the entire capping wafer may be made of a porous material.

The porous material enables high gas exchange between each recess and the environment.

The porous material may be a porous ceramic material, which provides heat resistance and enables the use of the sensor device in hot environments.

The porous material may have a hydrophobic surface. This may be achieved in many different ways. According to one alternative, a hydrophobic material is applied on the porous material. According to another alternative, the surface of the porous material is treated to be hydrophobic.

As an alternative to the gas permeable material being a porous material it is possible to use a non-porous polymer, wherein the polymer allows diffusion of gas through it.

The sensor part comprising micro- and/or nanostructures may be a photonic gas sensor parts and may comprise a light source, a detector, and a waveguide, which may be at least partially free hanging. This is a type of sensor which requires contact with gas for the sensing and which is sensitive for contamination with particles, dust and water from the dividing. If particles, dust or water is allowed to come in contact with the waveguide, the particles and the dust will contribute to a malfunction of the sensor. The light source may be an infrared, IR, light source. The light source may be a light emitting diode, a laser, or a resistive emitter, which is a metal or another conductive material with heats up when a current is forced through it.

The sensor parts do not have to comprise all parts necessary for a functioning sensor but may comprise only the parts which are configured to interact with the environment or any other combination of parts, i.e., waveguide and detector but no light source or waveguide and light source but no detector. An external light source or external detector might be coupled to the sensor device in different ways. One possibility is to configure a grating on the outside of the sensor device for coupling of light into the waveguide of the sensor device and/or for coupling of light out from the waveguide of the sensor device. The light source and/or the detector may be arranged in close proximity to the grating(s) on the outside of the sensor device. It is also possible to arrange a waveguide and/or an optical fiber between the light source and/or the detector and the grating(s) to allow the light source and/or detector to be placed further away from the sensor device.

The waveguide may be supported of pillars/posts extending from the device wafer, wherein the waveguide is free hanging between the pillars/posts. By having the waveguide free hanging between the pillars/posts the attenuation of the light due to surrounding material is minimized. Such a waveguide is negatively affected by dust, particles, and liquids, coming into contact with the waveguide. During fabrication the liquids is typically water used for cooling during dividing into individual sensor devices. During operation, the liquid is also typically water originating from water vapour condensation on the sensor device.

According to a second aspect, a semiconductor based sensor device is provided. The sensor device comprises a sensor part, which is configured to interact with the environment surrounding the sensor device. The sensor device comprises a semiconductor-based substrate, a sensor part comprising a micro- and/or nanostructure arranged on a device side of the substrate, a cap comprising a first side and a second side and a recess on the first side, wherein the cap is arranged with its first side on the substrate with a sensor part below the recess such that a cavity is formed between the recess and the substrate. The sensor device is characterized in that the cap is in contact with the substrate in contact areas arranged at the periphery of the recess, and in that the cap comprises at least one gas permeable section extending from the recess to the second side, to provide a gas passage between the recess and the environment surrounding the sensor device.

With the sensor device according to the second aspect a favourable sensor device is provided. The gas permeable sections provide some protection against, particles, dust, and water coming into contact with the sensor during operation of the sensor device. During operation, the gas permeable section also enables gas exchange between the sensor part and the environment surrounding the sensor device.

The sensor part do not have to comprise all parts necessary for a functioning sensor but may comprise only the part, which is configured to interact with the environment.

The capping wafer may be made entirely of a gas permeable material. This facilitates the fabrication of the capping wafer.

Alternatively, the capping wafer may be semiconductor-based and comprise gas permeable sections. According to this alternative, the capping wafer may comprise a semiconductor-based layer having apertures. The apertures may according to a first alternative be filled with gas permeable material. According to a second alternative, the semiconductor-based capping wafer may comprise a gas permeable layer on top of the semiconductor-based layer having apertures such that the apertures define the gas permeable sections.

The contact areas may completely enclose each recess such that gas exchange is possible only through the gas permeable material of the cap. In this way, the device is simplified in that all gas exchange is through the gas permeable section in the capping wafer. It is, however, possible to have gas permeable channels apart from the gas permeable section.

The gas permeable material may consist of a porous ceramic material. The ceramic material may be applied as a continuous layer above a semiconductor base layer of the capping wafer, wherein the semiconductor base layer is provided with openings defining the gas permeable sections. The part of the porous ceramic layer that covers an opening is a gas permeable section. Alternatively, the openings in the semiconductor base layer may be filled with a porous material such that the gas permeable sections are separate gas permeable sections. According to another alternative, the entire cap may be made of a porous material.

The porous material enables high gas exchange between each recess and the environment. The porous material may be a porous ceramic material, which provides heat resistance and enables the use of the sensor device in hot environments.

The porous material may have a hydrophobic surface. This may be achieved in many different ways. According to one alternative, a hydrophobic material is applied on the porous material.

According to another alternative, the surface of the porous material is treated to be hydrophobic.

As an alternative to the gas permeable material being a porous material it is possible to use a non-porous polymer, wherein the polymer allows diffusion of gas through it.

The sensor part comprising micro- and/or nanostructures may be photonic gas sensor parts and may comprise a light source, a detector, and a waveguide, which may be at least partially free hanging. This is a type of sensor which requires contact with gas for the sensing and which is sensitive for contamination with particles, dust, and water from the dividing. If particles and dust are allowed to come in contact with the waveguide, the particles and the dust will contribute to attenuation of the light in the waveguide. The light source may be an infrared, IR, light source. The light source may be a light emitting diode, a laser, or a resistive emitter, which is a metal or another conductive material with heats up when a current is forced through it.

The waveguide may be supported of pillars/posts extending from the device wafer, wherein the waveguide is free hanging between the pillars/posts. By having the waveguide free hanging between the pillars/posts the attenuation of the light due to surrounding material is minimized.

Such a waveguide is strongly affected by dust, liquids and particles coming into contact with the waveguide. During operation, the liquid is also typically water originating from water vapour condensation on the sensor device.

In the following preferred embodiments of the invention will be described with reference to the drawings on which:

### BRIEF DESCRIPTION OF THE DRAWINGS

FIG. 1-6 illustrates a method for production of a semiconductor based sensor device according to an embodiment.

FIG. 7 in a perspective view a sensor device according to FIG. 6.

FIG. 8 is a flow diagram of a method according to the present invention.

### DETAILED DESCRIPTION

In the following detailed description of embodiments, similar features in the different drawings are denoted with the same reference numerals. The drawings are not drawn to scale.

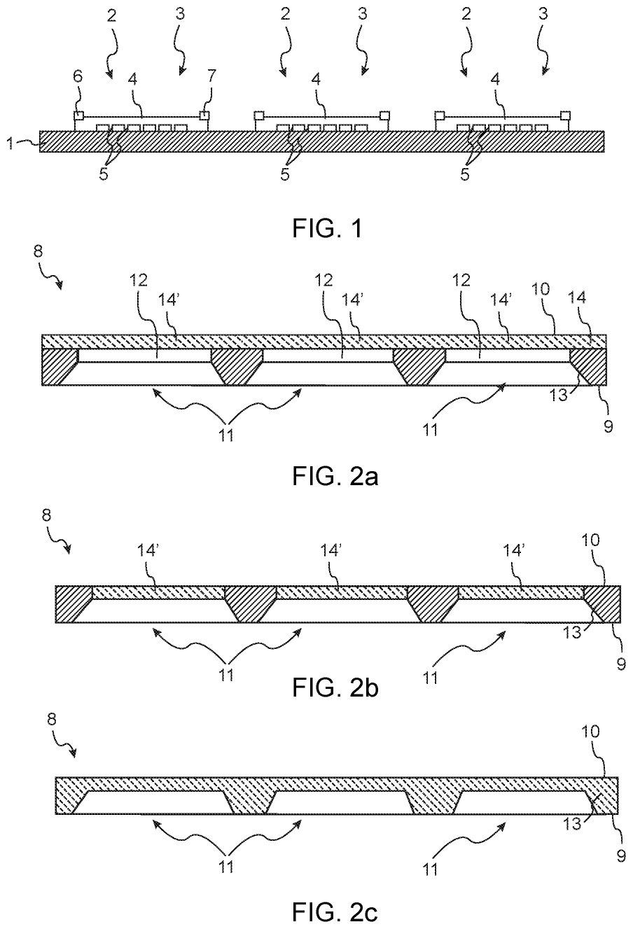

FIG. 1-6 illustrates the method for production of a semiconductor based sensor device. FIG. 1 shows in cross section a semiconductor based device wafer 1. A plurality of sensors 2 comprising micro- and/or nanostructures have been fabricated on different device areas 3 on the semiconductor-based device wafer 1. The semiconductor may be silicon, silicon nitride, silicon carbide, gallium arsenide or any other semiconductor on which a sensor may be fabricated. In the embodiment of FIG. 1, the sensors are infrared gas sensors. The sensor parts of each sensor 2 comprise a waveguide 4, which is supported on pillars/posts 5 extending from the device wafer 1 to the waveguide 4, such that the waveguide 4 is free hanging between the pillars/posts 5. In the embodiment of FIG. 1, the sensor parts of each sensor 2 also comprises a light source 6 such as a light emitting diode, LED, a laser diode, or a resistive emitter, in one end of the waveguide 4 and a photodetector 7 in the other end of the waveguide 4. The light source 6 is configured to transmit light into the waveguide 4 and the photodetector 7. The wavelength of the light from the light source is chosen to correspond to an absorption peak of the gas to be detected by the sensor. The wavelength is typically in the infrared wavelength band for most gases of interest. The cross sectional dimensions of the waveguide 4 are such that the light in the waveguide 4 forms an evanescent wave, which interacts with the gas surrounding the waveguide. Thus, the attenuation of the light in the waveguide 4 will depend on the concentration of the gas surrounding the waveguide.

It is possible to have the light source 6 and/or the photodetector outside the sensor device.

According to alternative embodiments, the sensor is not a gas sensor as shown in FIG. 1. In such alternative embodiments, the micro- and/or nanostructures may constitute pressure or humidity sensors. It is well known to skilled persons how pressure and/or humidity sensors based on micro- and/or nanostructures may be fabricated.

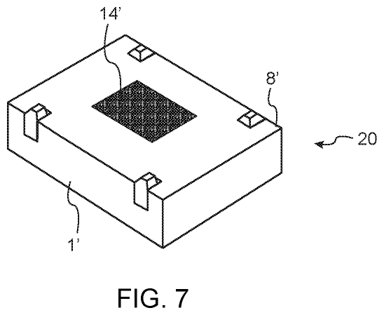

FIG. 2a shows a semiconductor based capping wafer 8 comprising a first side 9 and a second side 10 and a plurality of recesses 11 on the first side 9. The capping wafer 8 comprises at least one gas permeable section extending between each recess 11 and the second side 10, to provide a gas permeable passage between the recess 11 and the environment surrounding the sensor device 20 (FIG. 7). In the embodiment of FIG. 2a, the capping wafer comprises a semiconductor base layer 13 in which openings 12 have been fabricated. A continuous porous layer 14 is arranged on top of the semiconductor base layer 13. The porous ceramic layer covers the openings and constitutes a gas permeable membrane. The parts of the porous ceramic layer 14 covering the openings 12 constitute gas permeable sections 14′ providing a gas passage between the first side 9 and the second side 10. The recesses 11 and the openings may be fabricated using standard etching techniques. The porous ceramic layer may for example be made of alumina ceramics, silicon carbide ceramics, and zirconia oxide ceramics.

FIG. 2b shows a capping wafer 8 according to an alternative embodiment. In FIG. 2b, the openings 12 are filled with porous material. The porous material in the openings constitute gas permeable sections 14′ between the first side and the second side 10, to provide a gas passage between the first side 9 and the second side 10. In FIG. 2c, the entire capping wafer 8 is of a porous material.

As an alternative to the gas permeable material being a porous material it is possible to use a non-porous polymer, wherein the polymer allows diffusion of gas through it, such as, e.g., polydimethylsiloxane, PDMS, which is well known to have a rather high diffusion coefficient of CO2, and polymethyl methacrylate, PMMA.

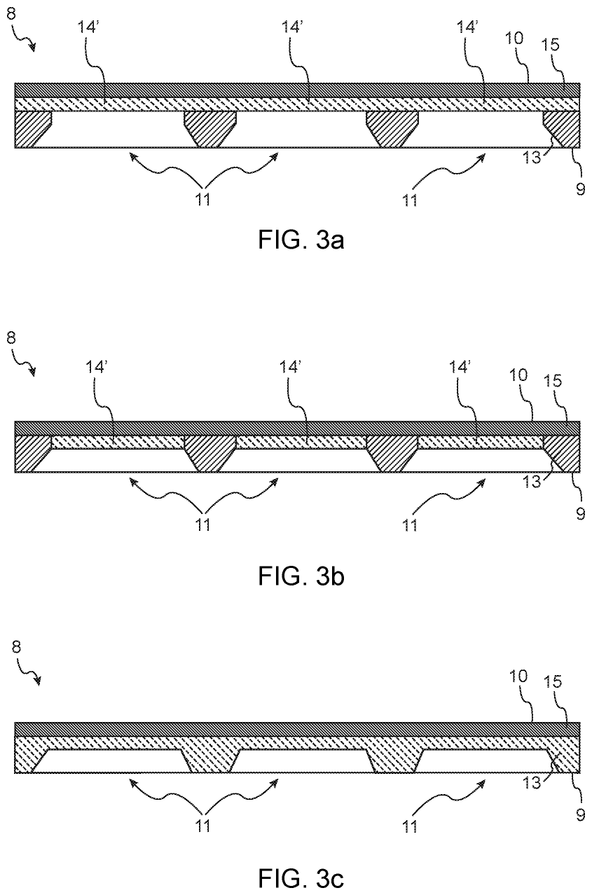

FIGS. 3a, 3b and 3c shows the capping wafers of FIGS. 2a, 2b, and 2c when a protective layer 15 has been applied on the second side 10 of the capping wafer 8. It is possible to apply a number of different protective layers.

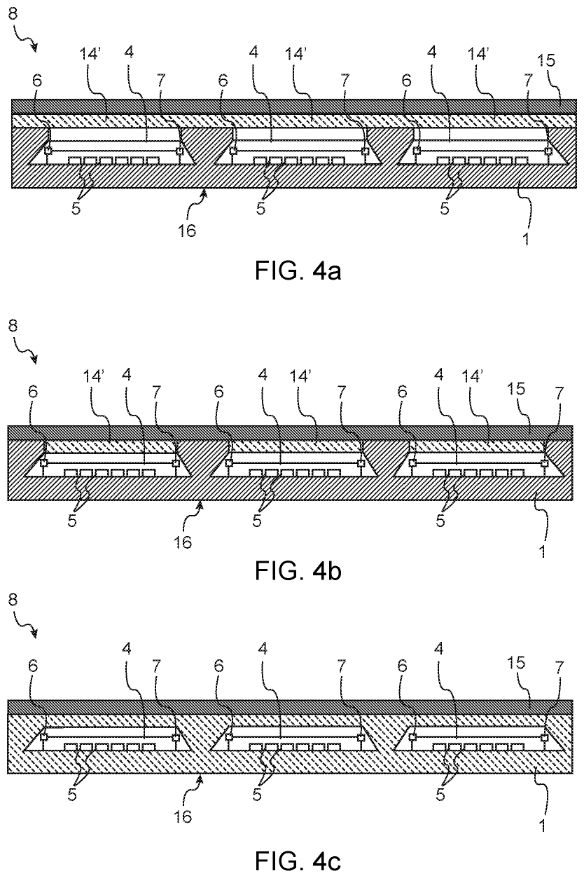

FIGS. 4a, 4b, and 4c shows the device wafer 1 with the capping wafer 8 attached with the first side 9 of the capping wafer 8 on the device wafer 1 with each sensor 2 arranged below a recess 11 such that a cavity is formed between each recess 11 and the device wafer 1. The capping wafer 8 is in contact with the device wafer 1 in contact areas 16 arranged at the periphery of the recesses 11. In the embodiments of FIGS. 4a and 4b the contact areas completely encloses each recess 11, such that gas exchange is possible only through the gas permeable section 14′. It would of course be possible to have also other gas permeable areas apart from the gas permeable sections 14′, but the embodiments of FIGS. 4a and 4b the fabrication is facilitated. It has been described above that the polymer layer 15 is applied on the capping wafer 8 before the capping wafer 8 is attached to the device wafer 1, but the polymer layer 15 may alternatively be applied after the attachment of the capping wafer 8 on the device wafer 1. The polymer layer 15 may be applied in liquid form. After application of the polymer layer 15 the polymer layer 15 is heat-treated for curing to solidify the liquid polymer. Alternatively, a solid sheet of polymer may be applied by lamination. In case the protective layer is a metal layer it may be applied using any standard technique known to skilled persons, such as, e.g., sputtering.

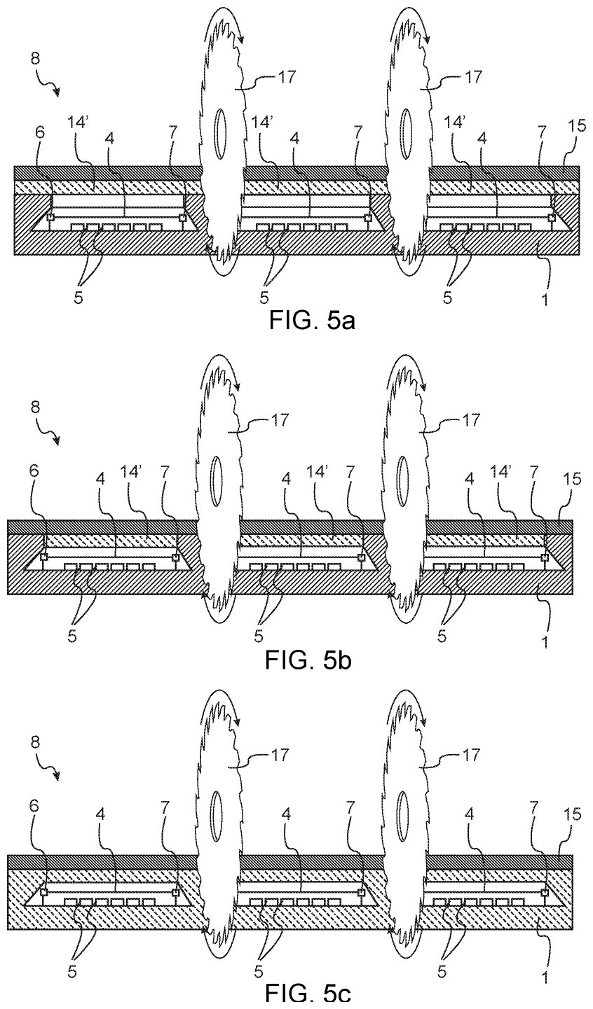

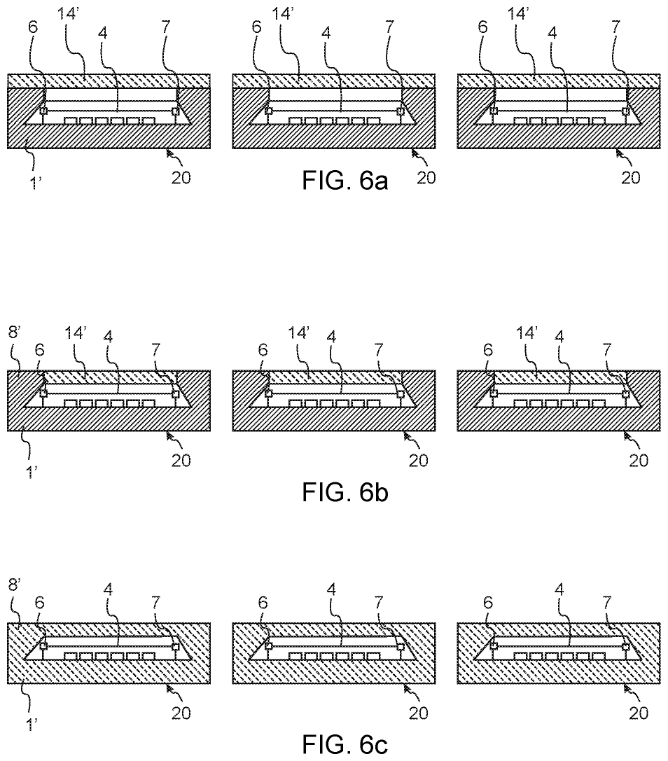

In FIGS. 5a, 5b, and 5c it is illustrated how the device wafer 1 and the attached capping wafer 8 according to FIGS. 4a and 4b, respectively, are divided into individual sensor devices 20. The dividing process may be performed using a rotating saw blade 17 while applying cooling water to the saw blade 17. Alternatively, a laser may be used for the dividing. During dividing particles are formed. The polymer layer 15 prevents the particles and/or the water from passing through the porous gas permeable sections 14′. After dividing the polymer layer is removed from all gas permeable sections 14′. The removal may be performed by for example dissolving the polymer layer or by oxygen plasma treatment. FIG. 6 shows the sensor devices 20 after dividing and after dissolving of the polymer layer 15.

FIGS. 6a, 6b, and 6c illustrate the sensor devices 20 after dividing the device wafers and the attached capping wafers in FIGS. 5a, 5b, and 5c, respectively. In FIGS. 6a, 6b, and 6c, the polymer layer 15 has been removed. The sensor devices comprise a substrate 1′ on which sensors 2 are arranged. The sensors 2 comprise a waveguide 4 which is supported on pillars/posts 5 extending from the substrate 1′ to the waveguide 4, such that the waveguide 4 is free hanging between the pillars/posts 5. Each sensor 2 comprises a light source 6 in one end of the waveguide 4 and a photodetector 7 in the other end of the waveguide 4. A cap 8′, comprising a gas permeable section 14′, covers the substrate and the sensor 2. The light source 6 may be, e.g., a laser a light emitting diode, LED, or a resistive element. FIG. 7 shows a sensor device 20 according to FIGS. 6a, 6b, and 6c in a perspective view.

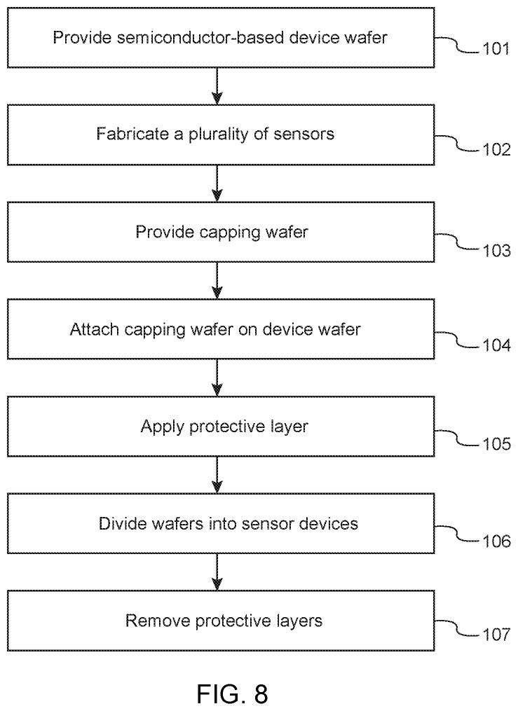

FIG. 8 is a flow diagram method for fabricating semiconductor based sensor devices comprising micro- and/or nanostructures, which are in communication with the environment surrounding the sensor devices of the method according to an embodiment of the invention. The flow diagram will be described with reference to FIGS. 1-4 described above. In a first step 101, a semiconductor based device wafer 1 is provided. In a second step 102, a plurality of sensors 2 comprising micro- and/or nanostructures are fabricated on different device areas 3 on the semiconductor based device wafer 1. In a third step 103 a capping wafer 8 comprising a first side 9 and a second side 10 and a plurality of recesses on the first side 9, is provided. In a fourth step 104 the first side of the capping wafer 11 is attached on the device wafer 1 with each sensor 2 arranged below a recess 11 such that a cavity is formed between each recess 11 and the device wafer 1. The capping wafer 8 is in contact with the device wafer 1 in contact areas 16 arranged at the periphery of the recesses 11. The capping wafer comprises at least one gas permeable section 14′ between each recess 11 and the second side 10, to provide a gas passage between the recess 11 and the environment surrounding the sensor device 20. In a fifth step 105 a protective layer in the form of a polymer layer 15 is applied on all gas permeable sections 14′ of the capping wafer 8. Steps 104 and 105 may be performed in the reverse order. The step of application of a polymer layer may comprise the step of heat treating a liquid polymer to solidify the polymer. In a sixth step 106, the device wafer 1 and the capping wafer 8 are divided into individual sensor devices 20. In a seventh step 107, the protective layer in the form of a polymer layer 15 is dissolved from the sensor devices 20.

The described embodiments may be amended in many ways without departing from the scope of the invention, which is limited only by the appended claims.

1. A method for fabricating semiconductor-based sensor devices comprising sensors which are configured to interact with the environment surrounding the sensor devices, comprising the steps of
providing a semiconductor-based device wafer,
fabricating a plurality of sensor parts comprising micro- and/or nanostructures on different device areas on a device side of the device wafer,
providing a capping wafer comprising a first side and a second side and a plurality of recesses on the first side,
attaching the first side of the capping wafer on the device side of the device wafer with each sensor part arranged below a recess such that a cavity is formed between each recess and the device wafer,
characterized in that the capping wafer is in contact with the device wafer in contact areas arranged at the periphery of the recesses, wherein the capping wafer comprises at least one gas permeable section between each recess and the second side, to provide a gas passage between the recess and the environment surrounding the sensor device, wherein the method further comprises the steps of
applying a protective layer on all gas permeable sections of the capping wafer,
dividing the device wafer and the attached capping wafer into individual sensor devices, and
removing (108) the protective layer from all gas permeable sections.

2. The method according to claim 1, wherein the capping wafer is made entirely of a gas permeable material.

3. The method according to claim 1, wherein the capping wafer is semiconductor-based and comprises gas permeable sections.

4. The method according to claim 1, wherein the contact areas completely enclose each recess after the step of dividing such that gas exchange is possible only through the gas permeable material of the capping wafer.

5. The method according to claim 4, wherein the step of applying a protective layer on all gas permeable sections comprises applying a protective layer covering the second side of the capping wafer.

6. The method according to claim 5, wherein the gas permeable material consists of a porous material.

7. The method according to claim 6, wherein the porous material has a hydrophobic surface.

8. The method according to claim 7, wherein the sensors comprising micro- and/or nanostructures are photonic gas sensors.

9. A semiconductor-based sensor device with a sensor part which is configured to interact with the environment surrounding the sensor device, comprising
a semiconductor-based substrate,
a sensor part comprising a micro- and/or nanostructure arranged on a device side of the substrate,
a cap comprising a first side and a second side and a recess on the first side, wherein the cap is arranged with its first side on the device side of the substrate with the sensor part arranged below the recess such that a cavity is formed between the recess and the substrate, characterized in that the cap is in contact with the substrate in contact areas arranged at the periphery of the recess, and in that the cap comprises at least one gas permeable section extending from the recess to the second side, to provide a gas passage between the recess and the environment surrounding the sensor device.

10. The sensor device according to claim 9, wherein the cap is made entirely of a gas permeable material.

11. The sensor device according to claim 9, wherein the cap is semiconductor-based and comprises at least one gas permeable section.

12. The sensor device according to claim 9, wherein the contact areas completely encloses each recess such that gas exchange is possible only through the gas permeable material of the cap.

13. The sensor device according to claim 9, wherein the gas permeable material consists of a porous material.

14. The method according to claim 13, wherein the porous material has a hydrophobic surface.

15. The sensor device according to claim 9, wherein the sensor part comprising micro- and/or nanostructures are photonic gas sensor parts.
